(19) United States
(12) Patent Application Publication
(10) Pub. No.: US 2021/0158159 A1
(43) Pub. Date: May 27, 2021

(54) ELECTRONIC CIRCUIT, NEURAL NETWORK, AND NEURAL NETWORK LEARNING METHOD

(71) Applicant: Hitachi, Ltd., Tokyo (JP)

(72) Inventor: Gou SHINKAI, Tokyo (JP)

(21) Appl. No.: 17/092,439

(22) Filed: Nov. 9, 2020

(30) Foreign Application Priority Data
Nov. 21, 2019 (JP) 2019-210549

(51) Int. Cl. G06N 3/08; H01L 29/66; G06N 10/00

(52) U.S. Cl. CPC G06N 3/08; G06N 10/00; H01L 29/66977

(57) ABSTRACT

To quickly find an optimal parameter for a neural network. An electronic circuit includes a quantum dot, a capacitance portion, a current portion, and a current adjustment portion. In this circuit, the quantum dot includes a first electrode, a second electrode, and a third electrode. The first electrode is connected to a first potential. The second electrode is connected to a first current source. The third electrode is connected to a second current source. The current portion discharges current from the second electrode or supplies current to the second electrode. The current adjustment portion adjusts a current of the current portion and outputs a parameter to adjust the current.

### CROSS-REFERENCE TO RELATED APPLICATION

The present application claims priority from Japanese application JP 2019-210549, filed on Nov. 21, 2019 the contents of which is hereby incorporated by reference into this application.

### BACKGROUND

The present invention relates to artificial intelligence or its machine learning technology.

Artificial intelligence is a technology that allows a computer to perform processes or a robot to operate based on a mathematical model called a neural network. The artificial intelligence is notable for its capability to perform processes or actions characteristic of humans. It is necessary to appropriately adjust parameters (also called weights) inside an artificial neural network according to the processes or actions so that the artificial intelligence can perform such processes or actions.

As the computer or the robot is required to perform more complicated processes or actions, the artificial neural network needs to be more complicated, thus increasing parameters to be adjusted. The time required to numerically acquire an optimal parameter value increases exponentially corresponding to the number of parameters. Therefore, the capability to acquire optimal parameters in a shorter time is one of the important issues for the development of artificial intelligence.

Solutions to this issue include the improvement of optimal value search algorithms and the development of dedicated hardware based on a GPU (Graphics Processing Unit). However, an iterative improvement method for respective parameters inevitably requires repetitive trials that increase the calculation time to find an optimal value.

There is also proposed a concurrent improvement method for all parameters. An example system uses an electronic circuit including a memristor as an electric resistance element that stores the amount of passed current (see Japanese Unexamined Patent Application Publication No. 2018-521397, US 2015/0278682 A1, and X. Wu, et al. “A CMOS Spiking Neuron for Brain-Inspired Neural Networks with Resistive Synapses and In-Situ Learning,” IEEE Transactions on Circuits and Systems II: Express Briefs, 62(11), 1088-1092 (2015)).

### SUMMARY

According to the method described in Japanese Unexamined Patent Application Publication No. 2018-521397, US 2015/0278682 A1, or X. Wu, et al. “A CMOS Spiking Neuron for Brain-Inspired Neural Networks with Resistive Synapses and In-Situ Learning”, IEEE Transactions on Circuits and Systems II: Express Briefs, 62(11), 1088-1092 (2015), a circuit is supplied with pulse signals representing an input value and a resulting output value at that time. Then, the resistance value of the memristor varies with the supplied current. An optimal parameter can be found by measuring the final memristor resistance value. However, it is difficult to find a material that is known to function as memristors and causes a resistance change to be large enough to make this concept fit for practical use.

There is a need for a technique that can quickly find an optimal parameter for the neural network based on other approaches.

According to a preferred aspect of the present invention, an electronic circuit includes a quantum dot, a capacitance portion, a current portion, and a current adjustment portion. In this circuit, the quantum dot includes a first electrode, a second electrode, and a third electrode. The first electrode is connected to a first potential. The second electrode is connected to a first current source. The third electrode is connected to a second current source. The current portion discharges current from the second electrode or supplies current to the second electrode. The current adjustment portion adjusts a current of the current portion and outputs a parameter to adjust the current.

According to a more specific configuration, an electron or a hole stably flows from the first potential to the first electrode and the second electrode via the quantum dot. A non-linear relationship is maintained between the current amount for electron or hole flowing between the quantum dot and the second electrode and the current amount for electron or hole flowing between the quantum dot and the third electrode.

According to a more specific configuration, the current adjustment portion determines the current amount I_{w} for the current portion based on a relational expression of I_{w}=w₁iₓ₁+w₂iₓ₂+ . . . +wₙiₓₙ+b, where I_{w} denotes the current amount for the current portion, iₓ₁ through iₓₙ denote current values of the first current source, w₁ through wₙ and b denote the parameters.

According to another preferred aspect of the present invention, a neural network is configured as a multi-layer network by connecting multiple electronic circuits to form multiple stages.

According to yet another preferred aspect of the present invention, a learning method of the above-described neural network allows each of the electronic circuits to perform a first step of supplying the first current source with a current value corresponding to a problem of training data; a second step of supplying the second current source with a current value corresponding to a solution of training data; a third step of outputting the parameter; and a fourth step of recording the parameter.

It is possible to quickly find an optimal parameter for the neural network.

### BRIEF DESCRIPTION OF THE DRAWINGS

FIG. 1 is a block diagram illustrating an overall learning system according to an embodiment;

FIG. 2 is a block diagram illustrating the inside of an electronic circuit 104;

FIG. 3 is a block diagram illustrating an internal configuration of an elemental component 204;

FIG. 4 is a block diagram illustrating internal processing of a variable adjustment portion 308;

FIG. 5 is a block diagram illustrating another internal processing of the variable adjustment portion 308;

FIG. 6 is a block diagram illustrating an internal mechanism of a current control portion 309;

FIG. 7 is a block diagram illustrating an internal mechanism of a voltage control portion 311;

FIG. 8 is a conceptual diagram illustrating parameters concerning the determination of input-side voltage vᵢ;

FIG. 9 is a flowchart illustrating a flow of learning according to an embodiment;

FIG. 10 is a block diagram illustrating the inside of the electronic circuit 104 according to a second embodiment;

FIG. 11 is a graph illustrating temporal variations in currents applied to current portions 202 and 203;

FIG. 12 is a graph illustrating temporal variations in the weight and the bias output from the electronic circuit 104; and

FIG. 13 is a schematic diagram illustrating the function of a neural network including four elemental components 204.

### DETAILED DESCRIPTION

Embodiments of the present invention will be described in further detail with reference to the accompanying drawings. However, the present invention is not interpreted based exclusively on the contents of the embodiments described below. It is further understood by those skilled in the art that various modifications may be made in the specific configurations without departing from the spirit and scope of the present invention.

In the configurations of the invention described below, the same portions or portions having similar functions use the same reference numerals in different drawings, and redundant description may be omitted.

When there is a plurality of elements having the same or similar functions, the same reference numeral may be given different additional characters. However, additional characters may be omitted when there is no need to make a distinction among the elements.

The notations such as “first,” “second,” and “third” in this specification, for example, are used to identify composing elements and do not necessarily limit the number of items, order, or contents thereof. A number to identify a composing element is used for each context. A number used in one context does not necessarily indicate the identical configuration in other contexts. A composing element identified by a given number may also function as a composing element identified by another number.

Positions, sizes, shapes, and ranges of respective configurations shown in the drawings, for example, may not represent actual ones to facilitate understanding of the invention. Therefore, the present invention is not necessarily limited to the positions, sizes, shapes, and ranges disclosed in the drawings, for example.

A neural network is broadly divided into a linear transformation part and a non-linear transformation part. The linear transformation represents that output is equal to the linear transformation of input. This equality relationship can be associated with Kirchhoff's current law in terms of circuits. A difference between both, if any, can be found by an increase or decrease in the node potential. An increase or decrease in the potential, if any, is balanced by adjusting a coefficient for the linear transformation.

In the present embodiments, the non-linear transformation uses electric conduction properties of a quantum dot (QD). A combination of these can configure an electronic circuit that works similarly to a neural network. The use of this circuit can find an optimal parameter for the neural network.

The inventors fabricated a special artificial neuron element that autonomously supplies a connection strength when input and output are given. The inventors conceived that a neural network comprised of this neuron element may be able to find a connection strength without searching by trial and error. To achieve this conception, the inventors have devised a special artificial neuron element that autonomously causes an appropriate connection strength under condition of input and output supplied in accordance with the natural force that aims to stabilize the energy. A conventional ordinary artificial neuron element determines an output depending on the input and the connection strength and differs from the artificial neuron element devised by the inventors in the function and the usage.

The following embodiments will describe the creation of an artificial neuron element that autonomously causes the connection strength to be an optimal value when input and output are given; and a technique of networking the artificial neuron elements. The embodiments use the non-linear electric conduction of a quantum dot. The quantum dot is a microscopic semiconductor or metal structure typically sized at several tens of nanometers. The quantum dot features non-ohmic resistivity allowing a current and a voltage to be disproportionate while an ordinary conductor features ohmic resistivity allowing a voltage and a current to be proportionate. The quantum dot is reported in M. Sugawara, “Self-Assembled InGaAs/GaAs Quantum Dots,” Semiconductors and Semimetals, Vol. 60 (1999), for example.

The use of a configuration as a combination of the quantum dot, the capacitance, and power supply makes it possible to design the input-output relationship so that a non-linear function represents the relationship between input current and output current. The charging energy of the capacitance is unstable under the condition of an input-output relationship that deviates from the non-linear function. The energy stabilization effect varies the input-output relationship to conform to the designed nonlinear function. Then, there autonomously occurs a flow of discharging a current to the outside or conversely supplying a current from the outside. This current can be associated with the connection strength of the artificial neuron. The measurement of the current makes it possible to find the optimal connection strength corresponding to input and output.

### First Embodiment

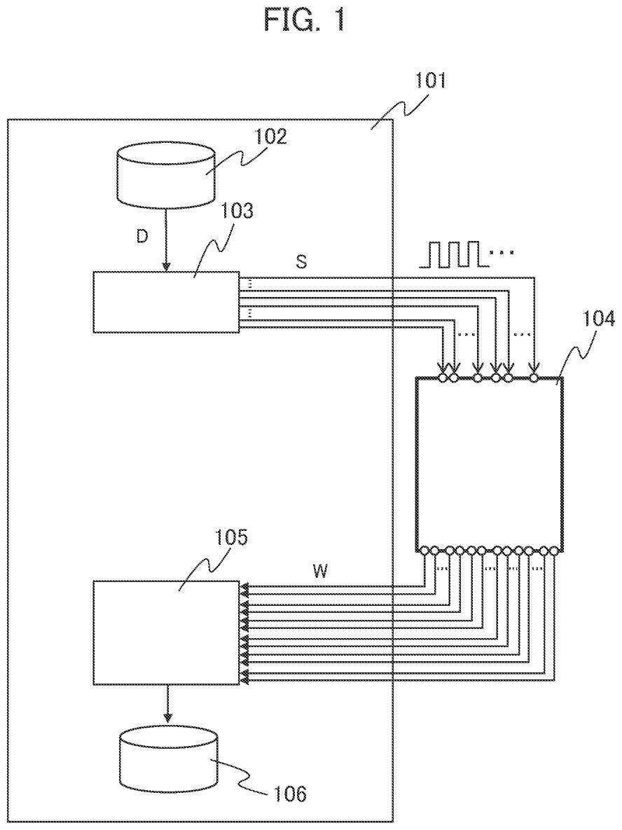

FIG. 1 is a diagram illustrating an overall learning system according to the embodiment. The learning system according to the present embodiment includes a learning system management portion 101 and an electronic circuit 104 to perform learning. The learning system management portion 101 can be configured as a general computer including an input device, an output device, a processing device, and a storage device, for example. FIG. 1 omits composing elements of a general computer and illustrates functional blocks specific to the present embodiment. The electronic circuit 104 includes a neural network as described later.

The learning system management portion 101 includes a storage 102 as a storage device to store a collection of datasets to be learned. The dataset is training data composed of a set of problem and solution data, for example. The question is input to the neural network. The solution is expected output from the neural network.

Each stored dataset D is converted into electric signal S by the data converter 103 and is periodically transmitted from an output device of the computer to the electronic circuit 104. The data converter 103 can be implemented as software by allowing the processing device to execute a program stored in the storage device, for example. The data converter 103 can be also configured as hardware including comparable functions.

When periodic electric signal S is input to the electronic circuit 104, weight W of the neural network output from the electronic circuit 104 starts to chronologically change. The change gradually decreases. When the change becomes small, the data converter 105 converts weight W into digital data. The storage 106 stores the digital data. Like the data converter 103, the data converter 105 can be configured as software or hardware. As a result, weight W of the learned neural network is stored.

When the neural network operates, inputting problem data to the neural network weighted by stored weight W outputs a required answer.

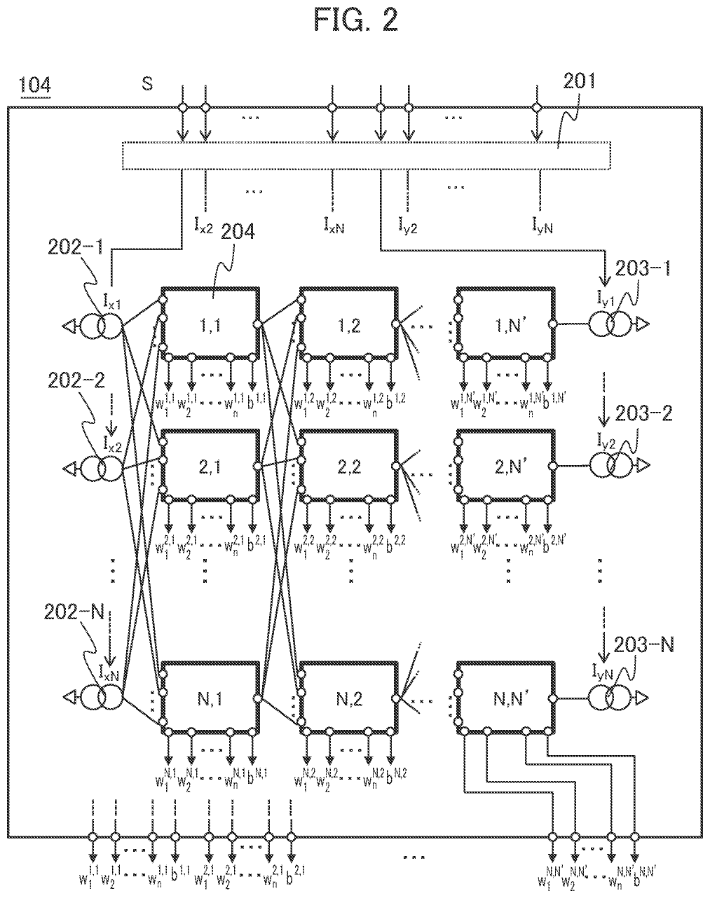

FIG. 2 is a diagram illustrating the inside of an electronic circuit 104. The electronic circuit 104 includes current portions 202-1 through 202-N and 203-1 through 203-N to generate currents, a current control portion 201 to control the current amount for these current portions, and a circuit-oriented elemental component 204.

The current control portion 201 controls the current amount for the current portions 202-1 through 202-N and 203-1 through 203-N based on electric signal S input from the learning system management portion 101. According to the present embodiment, electric signal S results from a voltage change. Therefore, the current control portion 201 includes a function of converting electric signal S based on the voltage into electric signals Iₓ₁ through I_{xN} and I_{y1} through I_{yN} based on the current. The conversion function is unnecessary if electric signal S results from a current change. Electrical signals Iₓ₁ through I_{xN} correspond to problem data of dataset D and are input to the neural network. Electric signals I_{y1} through I_{yN} correspond to solution data of dataset D and provide expected output from the neural network.

Generally, there are multiple elemental components 204 that correspond to nodes of the neural network. Input-output terminals of each elemental components 204 are connected to each other, configuring a multi-stage neural network as a whole. According to the present embodiment, the elemental components 204 are shaped into a matrix of N×N′. In the following description, the elemental components 204 may be described as elemental components “1, 1” through “N, N′” as illustrated in FIG. 2. Each elemental component 204 may use a different number of terminals in the electronic circuit 104. Depending on a neural network configuration, there may be a different number of elemental components such as N elemental components “1, 1” through “N, 1” at the input side and M elemental components “1, N′” through “M, N′” at the output side, for example. According to this configuration, the number of input-side current portions 202 differs from the number of output-side current portions 203.

The current portions 202-1 through 202-N and 203-1 through 203-N include input-side current portions 202-1 through 202-N and output-side current portions 203-1 through 203-N. The input-side current portions 202-1 through 202-N are supplied with electric signals Iₓ₁ through I_{xN} corresponding to problems in dataset D. The output-side current portions 203-1 through 203-N are supplied with electric signals I_{y1} through I_{yN} corresponding to solutions in dataset D.

According to the present embodiment, each elemental component 204 outputs weight signal w and bias b that are transmitted from the electronic circuit 104 to the learning system management portion 101. Weight signals output from elemental component “N, N′” are represented as w₁^{N, N′}, w₂^{N, N′} through wₙ^{N, N′}. The weight signal determines the weight of n input signals input to elemental component “N, N′.” The output from the elemental component 204 is equal to the sum of weighted input signals plus bias b. As described above, each elemental component 204 may use a different number of terminals in the electronic circuit 104. Each elemental component 204 may use a different value for n. In FIG. 2, the points represented by Iₓ₂ through I_{xN}, I_{y2} through I_{yN}, and the symbols such as w and b are electrically connected though not connected in the drawing for convenience sake.

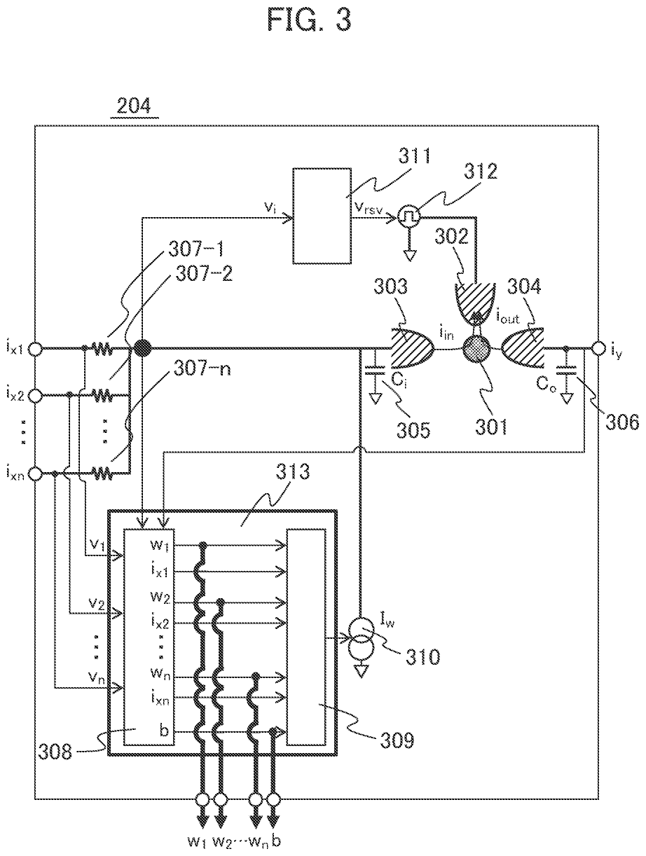

FIG. 3 illustrates an internal configuration of the elemental component 204. The elemental component 204 includes a quantum dot 301, quantum dot electrodes 302, 303, and 304, and capacitance portions 305 and 306. There are included electric resistance portions 307-1 through 307-n corresponding to n inputs iₓ₁ through iₓₙ, a current adjustment portion 313, and, a current portion 310 to supply current I_{w} determined by the current adjustment portion 313. Further, there are included a voltage control portion 311 and a voltage portion 312 to output a voltage determined by the voltage control portion 311. A semiconductor process can be used to create the circuit configuration including the quantum dot 301 as illustrated in FIG. 3.

The feature of the quantum dot 301 includes the provision of a nanoscale space region, a capability to enter and leave the space region due to the tunnel effect, and a capability to control the entry and exit of electrons between the quantum dot and the outside. This feature makes it possible to design various electric characteristics. The quantum dot is fabricated through the use of compound semiconductors, for example.

For example, suppose AlGaAs is doped with Si in a laminate structure of two types of compound semiconductor layers such as AlGaAs and GaAs. Then, the boundary between AlGaAs and GaAs forms a layer where conduction electrons called two-dimensional electron gas are accumulated. This electron can conduct in the x and y planes but not in the z-direction. Namely, the electrons are confined in the z-direction. When a negative voltage is applied to the gate electrode provided on the surface of the AlGaAs/GaAs laminate structure, a wall of electrostatic potential can be fabricated in the plane of the two-dimensional electron gas layer immediately below the gate electrode. This enables the confinement in the x and y directions. A dent of electrostatic potential to confine the electrons corresponds to the quantum dot. The existence region of electrons spreading outside the quantum dot works as an electric terminal of the quantum dot.

Including the case of parasitic capacitance, the capacitance portions 305 and 306 may not explicitly exist in the circuit. The current adjustment portion 313 includes a variable adjustment portion 308 and a current control portion 309 and outputs adjusted variables. The electrodes 302, 303, and 304 may be provided as two-dimensional electron gas spreading outside the above-mentioned quantum dot, for example, and may or may not have a physical electrode structure.

The quantum dot 301 illustrated in FIG. 3 appropriately adjusts the thickness of the tunnel barrier and the voltage of the voltage portion 312, and then allows the voltage portion 312 to stably supply electrons or holes to the electrodes 303 and 304 via the quantum dot 301, making it possible to apply a non-linear function to the relationship between current iᵢₙ and current iₒᵤₜ. The non-linear function provided by the quantum dot 301 can be associated with an activating function in the neural network node.

As an example of the above adjustment technique allows the thickness of the tunnel barrier between the quantum dot 301 and the electrode 302 in FIG. 3 to be sufficiently smaller than the thickness of the tunnel barrier between the quantum dot 301 and the electrode 303 or 304. In other words, the tunnel rate between the electrode 303 or 304 and the quantum dot 301 is smaller than the tunnel rate between the electrode 302 and the quantum dot 301. The voltage portion 312 is set to be sufficiently negative or positive (the sign is inverted depending on whether electrons or holes are confined in the quantum dot) compared to the voltage of the electrode 303 or 304.

Consequently, the voltage portion 312 stably supplies electrons or holes to the electrodes 302 and 303 via the quantum dot 301, making it possible to provide the non-linear relationship between the current amount for electron or hole flowing between the quantum dot 301 and the electrode 303 and the current amount for electron or hole flowing between the quantum dot 301 and the electrode 304.

The elemental component 204 illustrated in FIG. 3 is connected as a multi-stage configuration as illustrated in FIG. 2 to provide one neural network. Inputs iₓ₁ through iₓₙ to the elemental component 204 are output from the preceding elemental components. Output i_{y} from the elemental component 204 is input to the subsequent elemental component. As described later, signals Iₓ₁ through I_{xN} and I_{y1} through I_{yN} determined by signal S supplied to the electronic circuit 104 are considered to stabilize inputs and outputs from these elemental components at constant values after 40 μsec, for example. The current adjustment portion 313 and the voltage control portion 311 control the current portion 310 and the voltage portion 312 and may use a microcomputer, for example.

The current adjustment portion 313 works as a feedback circuit that actively reduces a temporal variation of potential vᵢ. If the current adjustment portion 313 is not provided, currents iₓ₁ through iₓₙ enter (or leave) the node indicated by potential vᵢ at the left in the drawing and leave (or enter) the same at the right. Theoretically, vᵢ is constant if the sum of these currents is zero. However, iₓ₁ through iₓₙ and iᵢₙ alone do not work to zeroize the sum. Therefore, if the current flowing into the node is excessive (or insufficient), the current adjustment portion 313 provides control to discharge (or supply) the current from the node so that the sum of currents becomes zero. The sum of iₓ₁ through iₓₙ and iᵢₙ generally does not become zero. Adjustable current I_{w} is then added to this sum and the sum of iₓ₁ through iₓₙ, iᵢₙ, and I_{w} is used to zeroize the currents flowing to and from the node A variation of potential vᵢ becomes zero when the sum of currents flowing to and from the node becomes zero. Therefore, the current adjustment portion 313 reduces a variation of vᵢ by zeroing the sum of currents input and output from the node.

Weight w takes some value even at each time until the temporal variation in potential vᵢ is reduced. It is formally possible to assign weights w to parameters of the neural network. As a result, the input-output relation y=f (x) of the neural network is formed but does not satisfy the required input-output relation. The configuration of the present embodiment can reduce the temporal variation in potential vᵢ and thereby acquire weight w in association with inputs to the node of the neural network.

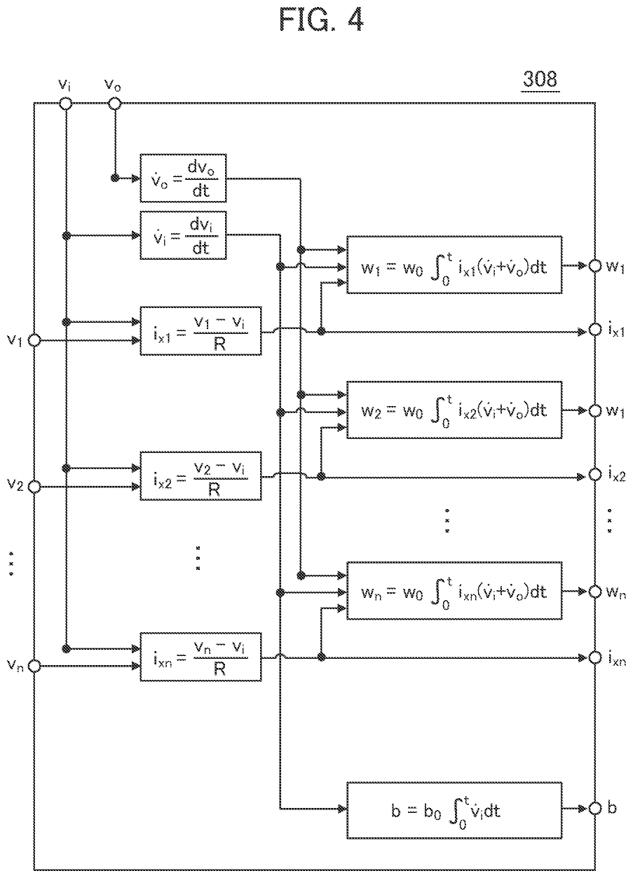

FIG. 4 illustrates the internal processing of the variable adjustment portion 308. Inputs to the variable adjustment portion 308 include input-side voltage vᵢ and output-side voltage vₒ of the quantum dot 301, and potentials v₁ through vₙ at input terminals for input signals iₓ₁ through iₓₙ to the elemental component 204. Outputs from the variable adjustment portion 308 include input signals iₓ₁ through iₓₙ, weights w₁ through wₙ of input signals iₓ₁ through iₓₙ, and bias b.

The processing of the variable adjustment portion 308 is not limited to digital or analog processing. In FIG. 4, R, wₒ, and bₒ represent constants. Constant R depends on the value of a resistor 307 in FIG. 3. The internal processing of the variable adjustment portion 308 is not limited to FIG. 4. Letter t represents time. The time here signifies the time for the circuit in FIG. 3 to learn parameters.

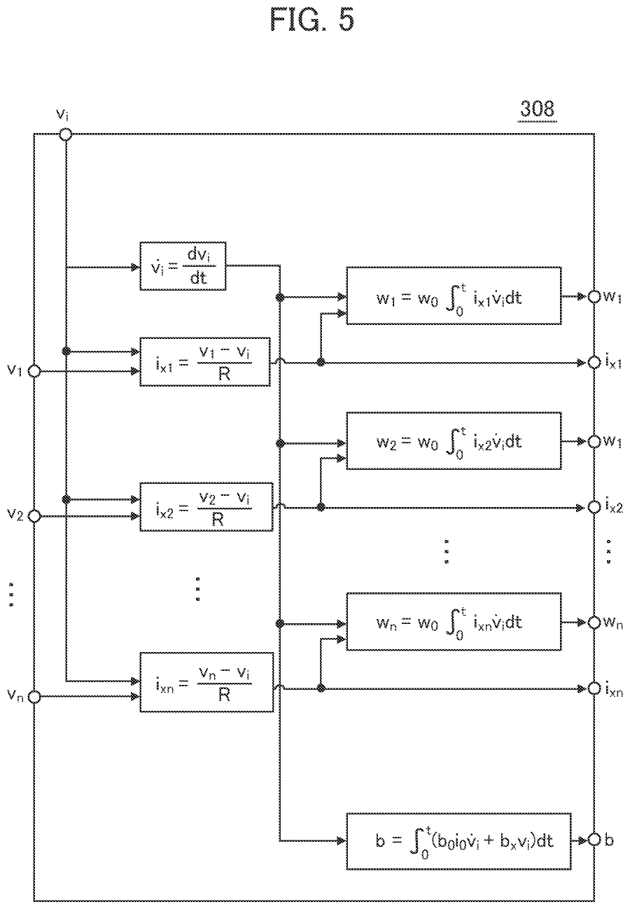

FIG. 5 illustrates another internal processing of the variable adjustment portion 308. As will be described later in this embodiment, an objective common to FIGS. 4 and 5 is to reduce a temporal variation in the input-side voltage vᵢ. Therefore, the processing just needs to reduce a temporal variation in input-side voltage vᵢ. The elemental component 204 can be assumed to maintain an equilibrium state when the temporal variation in input-side voltage vᵢ is zero, namely when the potential of the electrode 303 is stable. Input of a training dataset can find weight w and bias b necessary for the neural network from parameters for the elemental component 204 in an equilibrium state.

In the circuits in FIGS. 4 and 5, the definite integral from 0 through t by setting t to infinity can reproduce I_{w} in an equilibrium state. An actual circuit can be configured by setting t to 40 μsec or more, for example, as described later.

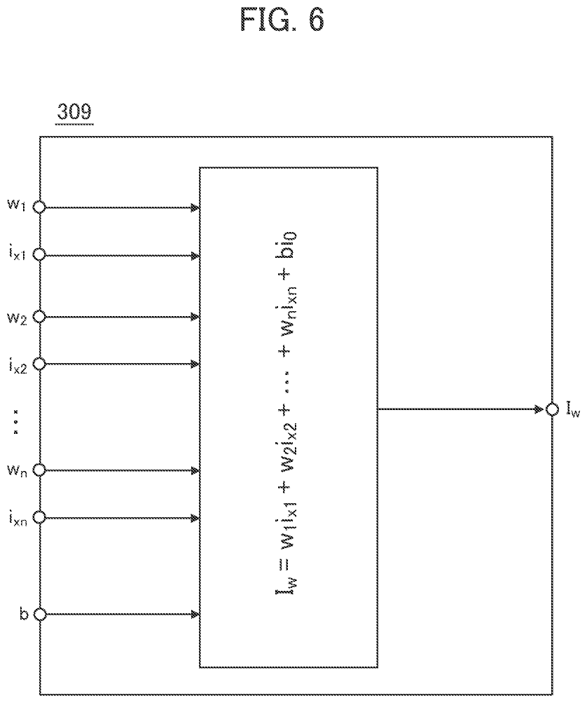

FIG. 6 illustrates an internal mechanism of the current control portion 309. Inputs to the current control portion 309 include input signals iₓ₁ through iₓₙ, weights w₁ through wₙ of input signals iₓ₁ through iₓₙ, and bias b. An output is current value I_{w} dependent on the inputs. The processing is not limited to digital or analog processing. The variable adjustment portion 308 and the current control portion 309 adjust the current amount for I_{w} of the current portion 310.

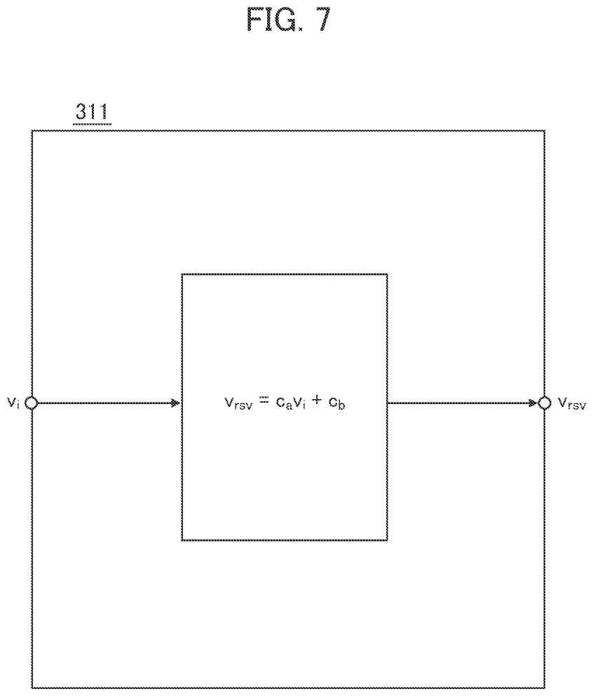

FIG. 7 illustrates an internal mechanism of the voltage control portion 311. The processing is not limited to digital or analog processing. The voltage control portion 311 outputs output vᵣₛᵥ in response to input-side voltage vᵢ to maintain the relationship as follows.

vᵣₛᵥ=cₐvᵢ+c_{b}

where cₐ and c_{b} denote constants. Constant cₐ may be set to zero. In this case, the voltage portion 312 outputs a constant voltage. The physical configuration of the quantum dot 301 and a voltage from the voltage control portion 311 are controlled to apply a non-linear function to the relationship between current iᵢₙ and current iₒᵤₜ. To provide this non-linear relationship, the voltage of the electrode 302 is set to be positively or negatively larger than at least a value resulting from dividing the product of the Boltzmann constant and the electron temperature in the electrode by the elementary charge.

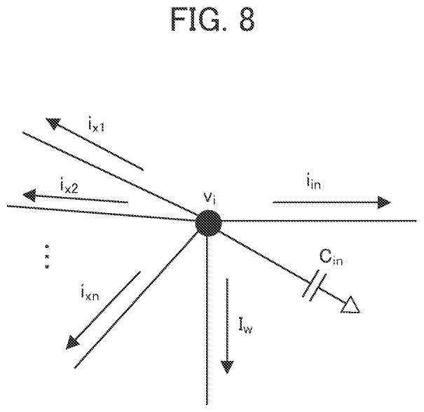

FIG. 8 illustrates a mechanism of how the circuit of the elemental component 204 can determine parameters for the neural network. FIG. 8 illustrates only currents iₓ₁ through iₓₙ, I_{w}, iᵢₙ, and capacitance cᵢ that are involved in determining input-side voltage vᵢ and are extracted from FIG. 3.

The temporal variation in input-side voltage vᵢ is described as in equation 1.

$$\begin{matrix}[ Math 1 ] & \\ \frac{{dv}_{i}}{dt} = \frac{1}{{C}_{i}} ( {i}_{in} + {i}_{x 1} + {i}_{x 2} + ⋯ + {i}_{xn} - {I}_{w} ) & ( 1 )\end{matrix}$$

The current adjustment portion 313 adjusts I_{w} so that the temporal variation in vᵢ becomes zero (to sufficiently decrease a potential variation of the electrode 303). As expressed in equation 2, this I_{w} depends on iₓ₁ through iₓₙ and constant current amount Iₒ, making it possible to adjust current amount I_{w} based on weights w₁ through wₙ as coefficients and bias b.

[Math 2]

I_{w}=w₁iₓ₁+w₂iₓ₂+ . . . +wₙiₓₙ+bi₀ (2)

If the temporal variation in vᵢ is set to zero in equation 1, equation 3 is derived from equation 2.

[Math 3]

i_{w}=(w₁−1)iₓ₁+(w₂−1)iₓ₂+ . . . +(wₙ−1)iₓₙ+bI₀ (3)

Equation 3 is a relational expression that represents iᵢₙ by using a linear transformation of iₓ₁ through iₓₙ. The linear transformation coefficients such as (w₁−1) through (wₙ−1) and b are comparable to parameters to be found for the neural network. Generally, the parameters to be found are described as (w₁−A) through (wₙ−A) and b, where A is a constant.

The function of the variable adjustment portion 308 will be described in detail. Damped vibration is generally described as the following equation 4, where x denotes the amount of displacement (extension of a spring, if any), t denotes the time, and a denotes a constant.

$$\begin{matrix}[ Math 4 ] & \\ \frac{{d}^{2} x}{{dt}^{2}} + 2 ζω \frac{dx}{dt} + {ω}^{2} x = a & ( 4 )\end{matrix}$$

Suppose equation 4 provides the form of designing a differential equation that allows a temporal variation in the state to follow. Then, it is possible to set dx/dt to 0 by setting t to be infinite. When the control is provided according to the variable adjustment portion 308, potential vᵢ can be described in the form of damped vibration like equation 4. The reason will be described below.

The equations for w₁ through wₙ and b described in the variable adjustment portion 308 of FIG. 5 are differentiated on both sides to yield equation 5.

$$\begin{matrix}[ Math 5 ] & \\ \begin{matrix}\frac{{dw}_{1}}{dt} = {w}_{0} {i}_{x 1} \frac{{dv}_{i}}{dt} \\ \frac{{dw}_{2}}{dt} = {w}_{0} {i}_{x 2} \frac{{dv}_{i}}{dt} \\ ⋮ \\ \frac{{dw}_{n}}{dt} = {w}_{0} {i}_{x n} \frac{{dv}_{i}}{dt} \\ \frac{db}{dt} = {b}_{0} {i}_{0} \frac{{dv}_{i}}{dt} + {b}_{x} {v}_{i}\end{matrix} & ( 5 )\end{matrix}$$

Differentiating both sides of equation 1 twice by t yields equation 6.

$$\begin{matrix}[ Math 6 ] & \\ \frac{{d}^{2} {v}_{i}}{d {t}^{2}} = \frac{1}{{C}_{i}} ( \frac{{di}_{in}}{d t} + \frac{d {i}_{x 1}}{d t} + \frac{d {i}_{x 2}}{d t} + ⋯ + \frac{d {i}_{x n}}{d t} - \frac{{dI}_{w}}{d t} ) & ( 6 )\end{matrix}$$

Differentiating both sides of the expression described in the current control portion 309 of FIG. 6 yields expression 7 as follows.

$$\begin{matrix} [ Math 7 ] & \\ \frac{{dI}_{w}}{dt} = \frac{{dw}_{1}}{dt} {i}_{x 1} + \frac{{dw}_{2}}{dt} {i}_{x 2} + ⋯ + \frac{{dw}_{n}}{dt} {i}_{xn} + {w}_{1} \frac{{di}_{x 1}}{dt} + {w}_{2} \frac{{di}_{x 2}}{dt} + {⋯w}_{n} \frac{{di}_{xn}}{dt} + \frac{db}{dt} {i}_{0} & ( 7 )\end{matrix}$$

Equation 8 is derived from equations 5 through 7.

$$\begin{matrix} [ Math 8 ] & \\ \frac{{d}^{2} {v}_{i}}{{dt}^{2}} + \frac{1}{{C}_{i}} ( {b}_{0} {i}_{0}^{2} + {w}_{0} ( {i}_{x 1}^{2} + {i}_{x 2}^{2} + ⋯ + {i}_{xn}^{2} ) ) \frac{{dv}_{i}}{dt} + \frac{1}{{C}_{i}} {b}_{x} {i}_{0} {v}_{i} + \frac{1}{{C}_{i}} ( \frac{{di}_{in}}{dt} + ( 1 - {w}_{1} ) \frac{{di}_{x 1}}{dt} + ( 1 - {w}_{2} ) \frac{{di}_{x 2}}{dt} + ⋯ + ( 1 - {w}_{n} ) \frac{{di}_{xn}}{dt} ) & ( 8 )\end{matrix}$$

Equation 8 can be arranged in the form of the differential equation for damped vibration shown in equation 4. Namely, equation 8 can be expressed like equation 9.

$$\begin{matrix} [ Math 9 ] & \\ \frac{{d}^{2} {v}_{i}}{{dt}^{2}} + 2 ζω \frac{{dv}_{i}}{dt} + {ω}^{2} {v}_{i} = \frac{1}{{C}_{i}} ( \frac{{di}_{in}}{dt} + ( 1 - {w}_{1} ) \frac{{di}_{x 1}}{dt} + ( 1 - {w}_{2} ) \frac{{di}_{x 2}}{dt} + ⋯ + ( 1 - {w}_{n} ) \frac{{di}_{xn}}{dt} ) \\ ζ = 1 + \frac{{w}_{0}}{{b}_{0}} ( {( \frac{{i}_{x 1}}{{i}_{0}} )}^{2} + {( \frac{{i}_{x 2}}{{i}_{0}} )}^{2} + ⋯ + {( \frac{{i}_{xn}}{{i}_{0}} )}^{2} ) \\ {ω}^{2} = \frac{{b}_{x} {i}_{0}}{{C}_{i}} = {b}_{0}^{2} \frac{{i}_{0}^{4}}{4 {C}_{i}^{2}} & ( 9 )\end{matrix}$$

When the variable adjustment portion 308 provides feedback control for w₁ through wₙ and b, the temporal variation of the potential vᵢ, as a damped vibration, can use (dvᵢ)/dt set to 0 by setting t to be infinite. Therefore, the feedback control described in the variable adjustment portion 308 can reduce the potential variation and consequently acquire weight w.

The description below explains the principle based on which the calculation of current control portion 309 determines w₁ through wₙ and b to zeroize the sum of currents iₓ₁ through iₓₙ, iᵢₙ, and Iw. For example, see the upper right equation containing w₁ on the left side in FIG. 5. The integrand on the right side is the product of iₓ₁ and dvᵢ/dt. When dvᵢ/dt is zero, the product of iₓ₁ and dvᵢ/dt is also zero. The integration is unaffected and the value of w₁ does not change. Namely, w₁ becomes constant when no variation is found in potential vᵢ. A case of dvᵢ/dt>0 signifies that too much current enters the node. Therefore, the amount of current output needs to be increased by increasing Iw to zeroize the sum of input-output currents for the node.

The setting (equation) for Iw provided by the current control portion 309 in FIG. 6 can increase Iw by increasing w₁. The condition of dvᵢ/dt>0 yields iₓ₁·dvᵢ/dt>0. See the equation containing w₁ on the left side of the variable adjustment portion 308 in FIG. 5. This circuit increases w₁ and increases Iw. The condition of dvᵢ/dt<0 reverses the result. Based on the above principle, the current adjustment portion 313 can reduce a temporal variation in the input-side voltage vᵢ and acquire weight w at that time.

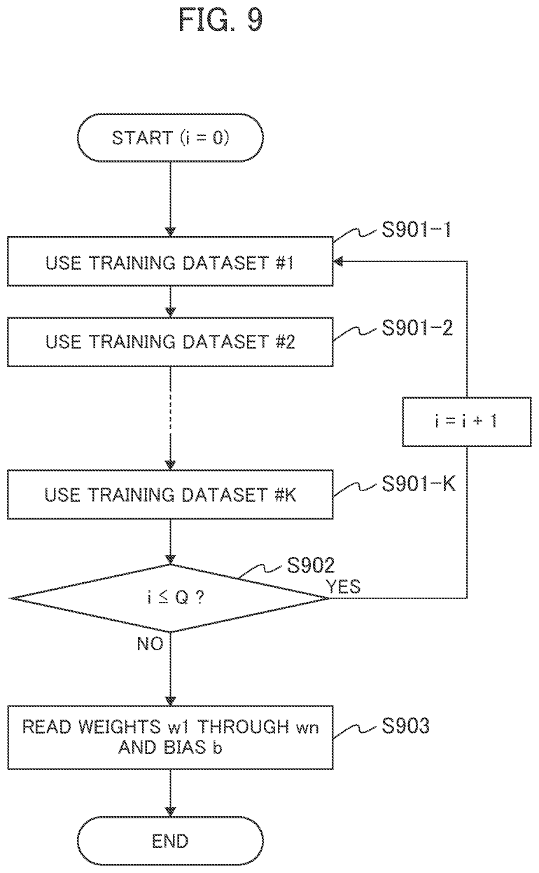

FIG. 9 illustrates a learning flow according to the present embodiment. Letter K denotes the number of datasets to be trained and Q denotes the number of iterations.

Multiple datasets are input to the electronic circuit 104 (S901-1 through S901-n). If there are multiple training datasets, a possible solution is to chronologically change the amount of current Iₓ₁ through Iₓₙ and I_{y1} through I_{yn}. For example, the current control portion 201 in FIG. 2 is used as a current source varying with the time to switch multiple current amounts corresponding to problems and answers for the training data at regular intervals. This process is repeated Q times (S902).

The above-described operation causes the charging energy of the elemental component 204 to vary with the time. If input and output are repeatedly modulated, the charging energy should behave to minimize its average. When there are many training datasets, the multiple sets of current amounts are switched at regular intervals. This operation is repeated Q times, allowing the values of weights w₁ through wₙ and bias b to converge. When the values stabilize after a predetermined time, the learning may be completed by reading weights w₁ through wₙ and bias b for the elemental components 204 (S903).

### Second Embodiment

The second embodiment specifically describes a special case of the learning procedure according to the first embodiment.

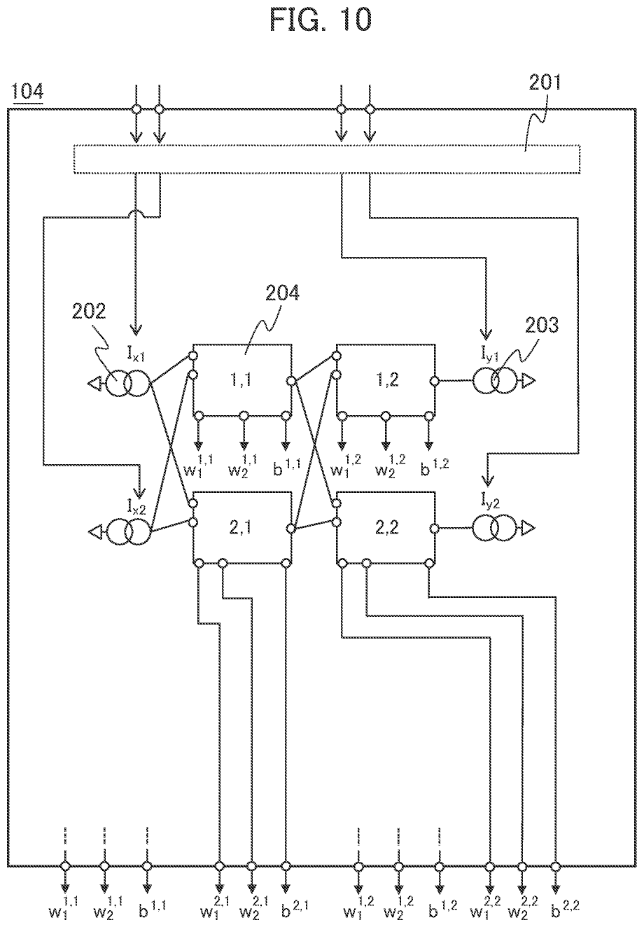

FIG. 10 is a block diagram illustrating the inside of the electronic circuit 104 according to the second embodiment. The electronic circuit 104 according to the second embodiment is limited to use the four elemental components 204. Suppose the storage 102 stores one data set of {0.2, 0.6}→{0.4, 0.6}, for simplicity. Based on this, the purpose is to find weights for a neural network that has the function of outputting the answer {0.4, 0.6} in reply to an input of the problem {0.2, 0.6}.

First, the storage 102 transmits {0.2, 0.6}→{0.4, 0.6} to the data converter 103. The data converter 103 converts this value according to the circuit. Here, the data converter 103 is assumed to multiply all values by 10⁻¹². As a result, the data converter 103 outputs {0.2×10⁻¹², 0.6×10⁻¹²}→{0.4×10⁻¹², 0.6×10⁻¹²}.

The current control portion 201 is assumed to convert a received value into ampere. In this case, the current portions 202 and 203 respectively supply currents Iₓ₁=0.2 pA, Iₓ₂=0.6 pA, I_{y1}=0.4 pA, and I_{y2}=0.6 pA.

The elemental components 204 output signals w₁^{1,1}, w₂^{1,1}, b^{1,1}, w₁^{2,1}, w₂^{2,1}, b^{2,1}, w₁^{1,2}, w₂^{1,2}, b^{1,2}, w₁^{2,2}, w₂^{2,2}, and b^{2,2} that are input to the data converter 105. Here, the data converter 105 is assumed to multiply an input value by 1. The storage 106 stores data resulting from converting a signal after a lapse of tₘₑₐₛ seconds from the transmission of data from the storage 102.

The description below explains a case where the storage 102 stores two data sets of {0.2, 0.6}→{0.4, 0.5} and {0.9, 0.4}→{0.2, 0.2}. Similar to the above, the data converter 103 and the current control portion 201 determine currents to be supplied to the current portions 202 and 203. When there are multiple datasets, currents Iₓ₁, Iₓ₂, I_{y1}, and I_{y2} are switched corresponding to the datasets at regular intervals, and this operation is repeated.

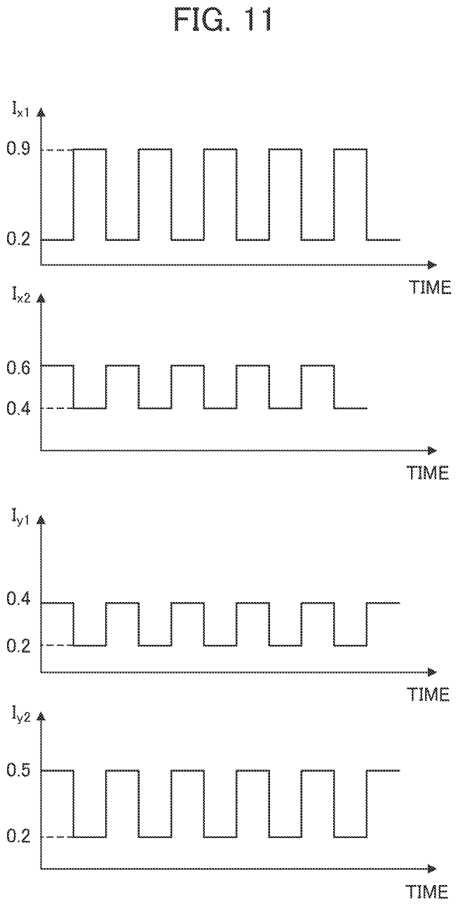

FIG. 11 illustrates temporal variations in currents Iₓ₁, Iₓ₂, I_{y1}, and I_{y2} supplied from the current control portion 201 to the current portions 202 and 203 when two datasets are used as above. Switching the currents as illustrated in FIG. 11 requires serialization between any of the storage 102, the data converter 103, the current control portion 201, and the current portion 202 or 203. Which part requires the serialization is included in design considerations.

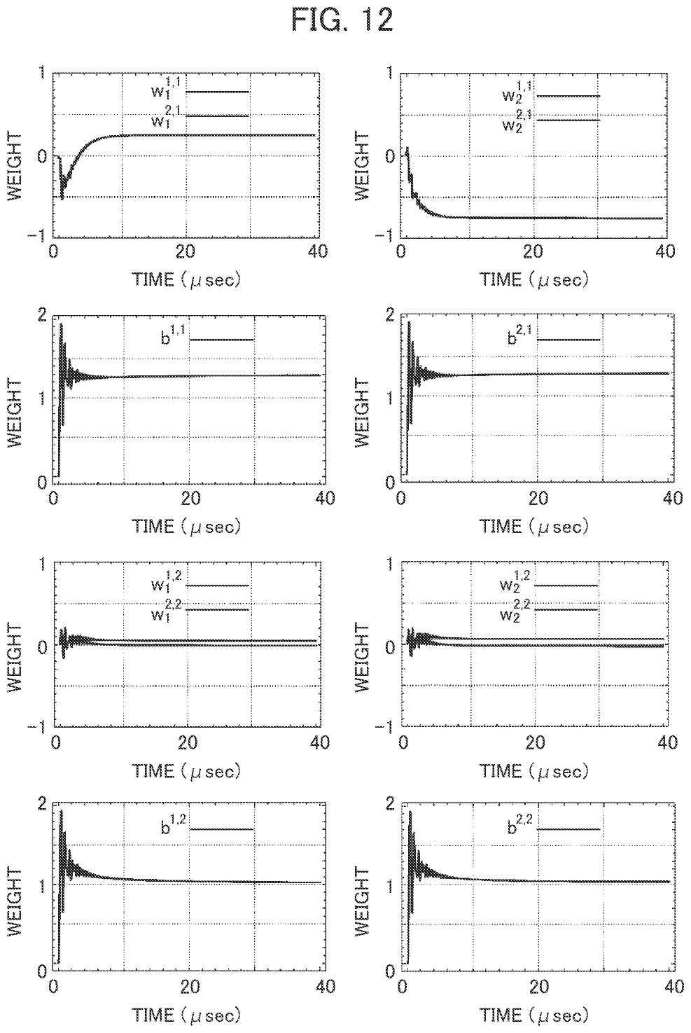

FIG. 12 is a graph illustrating temporal variations in weights and biases such as w₁^{1,1}, w₂^{1,1}, b^{1,1}, w₁^{2,1}, w₂^{2,1}, b^{2,1}, w₁^{1,2}, w₁^{2,2}, w₂^{2,2}, and b^{2,2} output from the electronic circuit 104 of FIG. 10 when the flow of FIG. 9 is performed under the above conditions. According to the example in FIG. 12, the graphs of w₁^{1,2} and w₁^{2,2} almost overlap and the graphs of w₂^{1,2} and w₂^{2,2} almost overlap. The graphs of w₂^{1,1} and w₁^{2,1} are not illustrated for convenience.

As seen from FIG. 12, the electronic circuit 104 can be assumed to maintain an equilibrium state in 40 μsec after the training dataset is repeatedly supplied. It is possible to determine that the values of current and voltage are sufficiently converged. As above, the storage 106 stores data after a lapse of tₘₑₐₛ seconds from the transmission of data from the storage 102. Then, this example favorably sets tₘₑₐₛ to 40 μsec or more.

The simulation of time characteristics on this circuit records values such as w₁^{1,1}=0.247, w₂^{1,1}=0.247, b^{1,1}=1.29, w₁^{2,1}=−0.754, w₂^{2,1}=−0.754, b^{2,1}=1.29, w₁^{1,2}=0.0625, w₂^{1,2}=−0.0216, b^{1,2}=1.03, w₁^{2,2}=0.048, w₂^{2,2}=−0.00669, and b^{2,2}=1.04.

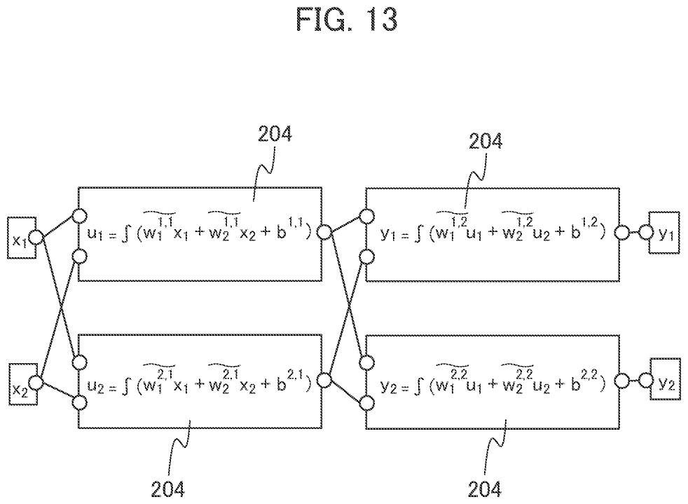

FIG. 13 is a schematic diagram illustrating the function of a neural network including four elemental components 204 in FIG. 10. The above-acquired values w₁^{1,1}, w₂^{1,1}, b^{1,1}, w₁^{2,1}, w₂^{2,1}, b^{2,1}, w₁^{1,2}, w₂^{1,2}, b^{1,2}, w₁^{2,2}, w₂^{2,2}, and b^{2,2} are assigned to the neural network illustrated in FIG. 13.

The variables in FIG. 13 are defined as expressed in equation 10 below.

$$\begin{matrix}[ Math 10 ] & \\ = {w}_{1}^{1 , 1} - 0.5 \\ = {w}_{2}^{1 , 1} - 0.5 \\ = {w}_{1}^{2 , 1} - 0.5 \\ = {w}_{2}^{2 , 1} - 0.5 \\ = {w}_{1}^{1 , 2} - 0.5 \\ = {w}_{2}^{1 , 2} - 0.5 \\ = {w}_{1}^{2 , 2} - 0.5 \\ = {w}_{2}^{2 , 2} - 0.5 & ( 10 )\end{matrix}$$

Function f (x) in FIG. 13 is expressed in equation 11 below. Function f (x) defines the relationship between input iᵢₙ and output iₒᵤₜ for the quantum dot 301 of the elemental component 204.

$$\begin{matrix}[ Math 11 ] & \\ f ( x ) = \frac{{e Γ}_{o}}{{( \frac{{e Γ}_{i}}{x} - 1 )}^{- 2} + 1} & ( 11 )\end{matrix}$$

In this equation, e=+−1.602×10-19 coulombs (the positive or negative depends on electrons and holes) denotes the elementary electric charge and Γᵢ and Γₒ denote constants. It is possible to set Γᵢ and Γₒ by controlling the thickness of the tunnel barrier between the quantum dot 301 and the electrode 303 or 304.

Here, eΓᵢ=1 and eΓₒ=1 are assumed in the above-described simulation of the time characteristics and the condition of the data converter 103. The above-described values are assigned to the neural network that is given {x₁, x₂}={0.2, 0.6} and then yields {y₁, y₂}={0.393, 0.512}. Meanwhile, the neural network is given {x₁, x₂}={0.9, 0.4} and then yields {y₁, y₂}={0.176, 0.233}. This proves the capability of acquiring the values approximate to training datasets {0.2, 0.6}→{0.4, 0.5} and {0.9, 0.4}→{0.2, 0.2}. As above, the electronic circuit according to the present embodiment can provide the required neural network.

According to the above-described embodiment, the neural network of the electronic circuit 104 is supplied with input electrical signals Iₓ₁ through I_{xN} and I_{y1} through I_{yN} dependent on dataset D of the training data. When the elemental component 204 including the quantum dot 301 illustrated in FIG. 3 enters an equilibrium state, input iₓ₁ through iₓₙ and output i_{y} for the elemental component 204 yield current I_{w}. Meanwhile, if current I_{w} is defined, input iₓ₁ through iₓₙ yields the corresponding output i_{y}.

According to the present embodiment, current I_{w} is given in equation 2. Therefore, it is possible to separately acquire weights w₁ through w_{N} and bias b for inputs iₓ₁ through iₓₙ. Therefore, it is possible to acquire the values of the parameters corresponding to the neural network configuration. It is possible to configure an electronic circuit that can yield weights for a neural network consistent with the situation at the time in reply to the provision of input and corresponding output without the use of a memristor. Therefore, it is possible to find an optimal value while improving all parameters in the neural network.

What is claimed is:

1. An electronic circuit comprising:
a quantum dot, a capacitance portion, a current portion, and a current adjustment portion,
wherein the quantum dot includes a first electrode, a second electrode, and a third electrode;
wherein the first electrode is connected to a first potential;
wherein the second electrode is connected to a first current source;
wherein the third electrode is connected to a second current source;
wherein the current portion performs one of operations that discharge current from the second electrode and supply current to the second electrode; and
wherein the current adjustment portion adjusts a current of the current portion and outputs a parameter used to adjust the current.

2. The electronic circuit according to claim 1,
wherein one of an electron and a hole stably flows from the first potential to the first electrode and the second electrode via the quantum dot; and
wherein a non-linear relationship is maintained between the current amount for one of an electron and a hole flowing between the quantum dot and the second electrode and the current amount for one of an electron and a hole flowing between the quantum dot and the third electrode.

3. The electronic circuit according to claim 1,
wherein a tunnel rate between the quantum dot and the first electrode is greater than a tunnel rate between the quantum dot and the second electrode and a tunnel rate between the quantum dot and the third electrode.

4. The electronic circuit according to claim 1,
wherein the capacitance portion and the current portion are arranged in parallel with a path between the second electrode and the first current source.

5. The electronic circuit according to claim 1,
wherein the current adjustment portion uses a current value of the first current source and the parameter to determine a current amount for the current portion.

6. The electronic circuit according to claim 5,
wherein the current adjustment portion uses the parameter to weight the current value of the first current source.

7. The electronic circuit according to claim 6,
wherein the current adjustment portion determines current amount I_{w} for the current portion based on a relational expression of
I_{w}=w₁iₓ₁+w₂iₓ₂+ . . . +wₙiₓₙ+b
when a current amount for the current portion is defined as I_{w}, current values of the first current source are defined as iₓ₁ through iₓₙ, and the parameters are defined as w₁ through wₙ and b.

8. The electronic circuit according to claim 7,
wherein I_{w} is a value when an electronic circuit maintains an equilibrium state.

9. The electronic circuit according to claim 8,
wherein the equilibrium state causes a potential variation in the second electrode to be sufficiently small.

10. A neural network configured as a multi-layer network by connecting a plurality of the electronic circuits according to claim 1 to form a plurality of stages.

11. A learning method of the neural network according to claim 10, allowing each of the electronic circuits to perform:
a first step of supplying the first current source with a current value corresponding to a problem of training data;
a second step of supplying the second current source with a current value corresponding to a solution of training data;
a third step of outputting the parameter; and
a fourth step of recording the parameter.

12. The learning method of the neural network according to claim 11, performing:
a fifth step of configuring a neural network corresponding to the neural network according to claim 10; and
a sixth step of setting a value corresponding to the parameter for each of the electronic circuits, the value being comparable to the connection strength of a neural network constructed at the fifth step.

13. The learning method of the neural network according to claim 11,
wherein a set of a plurality of problems and solutions is used as the training data by modulating a current value supplied to the first current source and the second current source, repeating the modulation a plurality of times, and performing the third step after a predetermined time.
